(19) United States
(12) Patent Application Publication
(10) Pub. No.: US 2010/0216064 A1
(43) Pub. Date: Aug. 26, 2010

(54) SEMICONDUCTOR-DEVICE MANUFACTURING METHOD, COMPUTER PROGRAM PRODUCT, AND EXPOSURE-PARAMETER CREATING METHOD

(76) Inventors: Michiya Takimoto, Kanagawa (JP); Hiromitsu Mashita, Kanagawa (JP); Toshiya Kotani, Tokyo (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/683,943

(22) Filed: Jan. 7, 2010

(30) Foreign Application Priority Data
Feb. 23, 2009 (JP) 2009-039864

(51) Int. Cl. G03F 7/20; G06F 17/50

(52) U.S. Cl. 430/30; 700/103; 700/110

(57) ABSTRACT

A semiconductor-device manufacturing method includes: correcting a systematic component of process proximity effect, which occurs in a process other than exposure processing to thereby set a target pattern after exposure; adjusting an exposure parameter such that a difference between a dimension of the target pattern and a pattern dimension after the exposure is within tolerance; and forming, when an exposure margin calculated from the exposure parameter by using the exposure the random component of fluctuation in the process proximity effect is within the tolerance, a pattern on a semiconductor substrate with the adjusted exposure parameter.

### CROSS-REFERENCE TO RELATED APPLICATIONS

This application is based upon and claims the benefit of priority from the prior Japanese Patent Application No. 2009-039864, filed on Feb. 23, 2009; the entire contents of which are incorporated herein by reference.

### BACKGROUND OF THE INVENTION

1. Field of the Invention

The present invention relates to a semiconductor-device manufacturing method, a computer program product, and an exposure-parameter creating method.

2. Description of the Related Art

In recent years, microminiaturization of patterns in semiconductor manufacturing technologies is remarkable. Semiconductors having a minimum processing dimension of 0.065 micrometer are mass-produced. Such pattern microminiaturization is realized by the rapid progress of micro pattern forming technologies such as a mask process technology, a lithography process technology, and an etching process technology.

In the times when pattern sizes were sufficiently large, the tolerance for dimensional fluctuation due to process fluctuation was large. Therefore, patterns satisfying required specifications could be formed on a wafer by tuning process conditions for each process.

However, in recent years, the tolerance for dimensional fluctuation decreases according to the microminiaturization of patterns. It is difficult to satisfy required specifications simply by individually tuning process conditions. As a method of satisfying required specifications for dimensional fluctuation, there is an optical proximity correction (OPC) technology for correcting dimensional fluctuation due to layout dependency of patterns (proximity effect). There is also a method of tuning any one of process conditions taking a plurality of manufacturing processes into account.

For example, a method of creating process parameters disclosed in Japanese Patent Application Laid-Open No. 2003-303742 includes: a step of preparing a parameter group including a plurality of process parameters; a step of correcting a first pattern based on the parameter group to calculate a second pattern; a step of predicting, based on the parameter group and the second pattern, a third pattern formed on a semiconductor substrate by an etching process; a step of comparing the third pattern and the first pattern to obtain an evaluation value; a step of determining whether the evaluation value satisfies a predetermined condition; a step of correcting, when it is determined that the evaluation value does not satisfy the predetermined condition, the process parameters included in the parameter group and returning to the step of correcting the first patter; and a step of determining, when it is determined that the evaluation value satisfies the predetermined condition, the process parameters included in the parameter group as final process parameters.

In the method disclosed in Japanese Patent Application Laid-Open No. 2003-303742, the process parameters are tuned by directly using fluctuation in process proximity effect (PPE) that fluctuates because of various factors.

### BRIEF SUMMARY OF THE INVENTION

A semiconductor-device manufacturing method according to an embodiment of the present invention comprises: correcting fluctuation in process proximity effect, which occurs in a process including a processing process other than exposure processing in forming a pattern on a semiconductor substrate, to thereby set a target pattern after exposure formed on a resist for forming the pattern;

adjusting an exposure parameter used in the exposure processing on the semiconductor substrate such that a difference between a dimension of the target pattern and a pattern dimension after the exposure is within tolerance; calculating an exposure margin of the pattern using the exposure parameter and determining whether the exposure margin is within tolerance; determining, when it is determined that the exposure margin is within the tolerance, the adjusted exposure parameter as an exposure parameter used in the exposure processing on the semiconductor substrate; performing the exposure processing on the semiconductor substrate using the determined exposure parameter to thereby form a pattern on the semiconductor substrate; setting, in setting the target pattern, the target pattern using a systematic component in the process proximity effect; and calculating, in calculating the exposure margin, the exposure margin using a random component, which fluctuates at random, in fluctuation of the process proximity effect.

A computer program product executable by a computer and having a computer readable recording medium includes a plurality of commands for determining an exposure parameter according to an embodiment of the present invention, wherein the commands cause the computer to execute: correcting fluctuation in process proximity effect, which occurs in a process including a processing process other than exposure processing in forming a pattern on a semiconductor substrate, to thereby set a target pattern after exposure formed on a resist for forming the pattern; adjusting an exposure parameter used in the exposure processing on the semiconductor substrate such that a difference between a dimension of the target pattern and a pattern dimension after the exposure is within tolerance; calculating an exposure margin of the pattern using the exposure parameter and determining whether the exposure margin is within tolerance; determining, when it is determined that the exposure margin is within the tolerance, the adjusted exposure parameter as an exposure parameter used in the exposure processing on the semiconductor substrate; setting, in setting the target pattern, the target pattern using a systematic component in the process proximity effect; and calculating, in calculating the exposure margin, the exposure margin using a random component, which fluctuates at random, in fluctuation of the process proximity effect.

An exposure-parameter creating method according to an embodiment of the present invention comprises: correcting fluctuation in process proximity effect, which occurs in a process including a processing process other than exposure processing in forming a pattern on a semiconductor substrate, to thereby set a target pattern after exposure formed on a resist for forming the pattern; adjusting an exposure parameter used in the exposure processing on the semiconductor substrate such that a difference between a dimension of the target pattern and a pattern dimension after the exposure is within tolerance; calculating an exposure margin of the pattern using the exposure parameter and determining whether the exposure margin is within tolerance; determining, when it is determined that the exposure margin is within the tolerance, the adjusted exposure parameter as an exposure parameter used in the exposure processing on the semiconductor substrate; performing the exposure processing on the semiconductor substrate using the determined exposure parameter to thereby form a pattern on the semiconductor substrate;

setting, in setting the target pattern, the target pattern using a systematic component in the process proximity effect; and calculating, in calculating the exposure margin, the exposure margin using a random component, which fluctuates at random, in fluctuation of the process proximity effect.

### BRIEF DESCRIPTION OF THE DRAWINGS

FIG. 1 is a diagram for explaining the concept of exposure parameter creation according to an embodiment of the present invention;

FIG. 2 is a block diagram of the configuration of an exposure-parameter creating apparatus according to the embodiment;

FIG. 3 is a flowchart for explaining a processing procedure of an exposure-parameter creating method;

FIGS. 4A and 48 are graphs for explaining a systematic component and a random component of PPE fluctuation information;

FIG. 5 is a graph for explaining pattern dependency of PPE;

FIG. 6 is a diagram for explaining a CD distribution in respective processes;

FIG. 7 is a graph fox explaining a dimension of a lithography target;

FIGS. 8A and 88 are graphs for explaining an exposure margin set when an exposure condition is not adjusted; and

FIG. 9 is a diagram of the hardware configuration of the exposure-parameter creating apparatus.

### DETAILED DESCRIPTION OF THE INVENTION

Exemplary embodiments of the present invention are explained in detail below with reference to the accompanying drawings. The present invention is not limited by the embodiments. Exposure parameters in the embodiments are parameters that affect optical proximity effect such as exposure wavelength, a lens numerical aperture, an illumination shape, and a luminance distribution of an illumination.

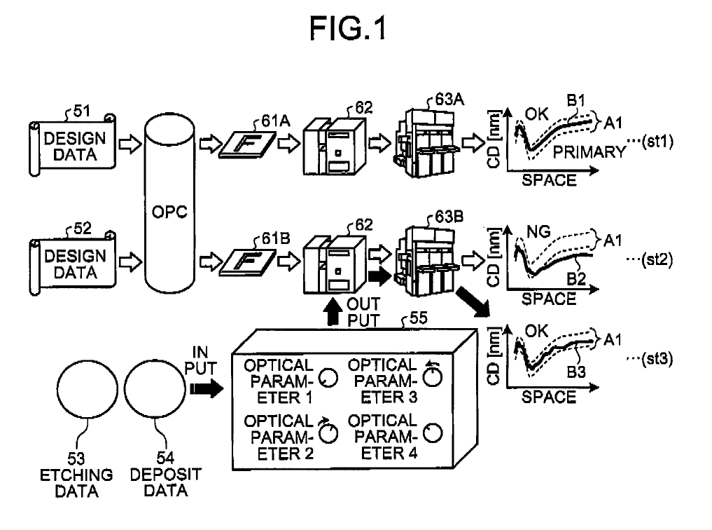

FIG. 1 is a diagram for explaining the concept of exposure parameter creation according to an embodiment of the present invention. When patterns are formed on a semiconductor substrate such as a wafer, first, patterns are formed on the wafer under standard conditions and, if a distribution of pattern dimensions after processing (post-processing CD distribution B1) is within tolerance A1, thereafter, patterns are formed on the wafer under new conditions.

The standard conditions are, for example, conditions (design data, an exposure condition, a body of a processing apparatus, etc.) used in a development stage of semiconductor devices. The new conditions are, for example, conditions such as apparatus deployment and derived products (conditions such as a plurality of apparatuses and derived product types) used in mass-producing semiconductor devices. In the new conditions, design data is changed or bodies of processing apparatuses such as an exposure apparatus and an etching apparatus are changed from those in the standard conditions.

When patterns are formed on the wafer under the standard conditions, first, OPC is applied to design data 51 of the standard conditions. A reticle (a photomask) 61A is manufactured by using design data after the OPC. An exposing apparatus 62 performs exposure processing for the wafer under the exposure condition of the standard conditions using the reticle 61A. Thereafter, a processing apparatus 63A (e.g., an etching apparatus, a chemical vapor deposition (CVD) apparatus or a developing apparatus) other than an exposing apparatus performs processing (e.g., etching or film formation) for the wafer. When the etching apparatus is used, for example, patterns formed by processing a film to be processed using a resist pattern as a mask are obtained as post-processing patterns. When the CVD apparatus is used, for example, sidewall patterns formed on sidewalls of hard mask patterns formed by processing a resist pattern or processing a hard mask material using the resist pattern as a mask are obtained as post-processing patterns. These processes can be combined. For example, patterns formed by processing the film to be processed using the sidewall patterns as masks can be obtained as post-processing patterns. Consequently, post-processing patterns having a post-processing CD distribution B1 within the tolerance A1 are formed on the wafer (st1).

When patterns are formed on the wafer under the new conditions, the OPC is applied to design data 52 of the new conditions by using an OPC rule and an OPC program same as those of the standard conditions. A reticle 61B is manufactured by using design data after the OPC. The exposing apparatus 62 performs exposure processing for the wafer using the reticle 61B. Thereafter, a processing apparatus 63B other than an exposing apparatus performs processing for the wafer.

When a processing apparatus other than an exposing apparatus is changed from the processing apparatus 63A to the processing apparatus 63B in the apparatus deployment, a pattern dimension fluctuates because of proximity effect fluctuation that occurs in a processing process or the like by the processing apparatus. When the design data is changed to the derived product type or the like from that in the standard conditions, a pattern dimension fluctuates because of proximity effect fluctuation. In this way, there are two kinds of fluctuation, i.e., the proximity effect fluctuation that occurs when the processing apparatus is changed and the proximity effect fluctuation that occurs when the design data is changed (the derived product type). Therefore, when exposure is performed under the new conditions, if the wafer is exposed under a condition same as the exposure condition of the standard conditions, a post-processing CD distribution B2 may deviate from the tolerance A1 (st2).

Therefore, in this embodiment, when exposure is performed under the new conditions, exposure parameters (an optical parameter, etc.) in a lithography process are adjusted based on etching data 53, deposit data (film formation data) 54, and the like (PPE fluctuation information explained later). In other words, fluctuation in a pattern dimension due to proximity effect fluctuation that occurs in a manufacturing process such as an etching process is relaxed by exposure parameter adjustment in the lithography process. Consequently, patterns having a post-processing CD distribution B3 within the tolerance A1 are formed on the wafer (st3). In this embodiment, a plurality of exposure parameters in the lithography process are created according to the PPE fluctuation information. When the exposure processing for the wafer is performed, exposure is performed with exposure parameters corresponding to a systematic component (a systematic component 21 explained later) of the PPE fluctuation information. In the following explanation, the processing apparatus other than an exposing apparatus is the etching apparatus and the processing for the wafer after the exposure is etching.

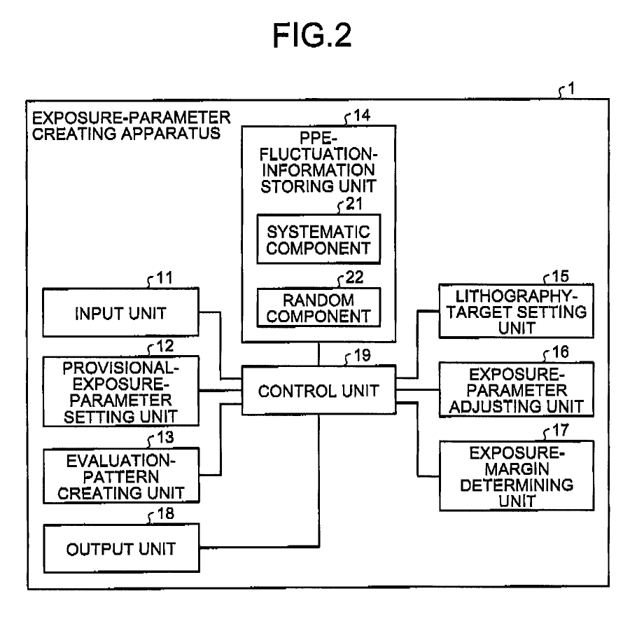

FIG. 2 is a block diagram of the configuration of an exposure-parameter creating apparatus according to this embodiment. An exposure-parameter creating apparatus 1 is an apparatus such as a computer that adjusts the exposure parameters in the lithography process according to pattern dimension fluctuation due to the PPE (fluctuation in a pattern dimension due to proximity effect fluctuation). The exposure-parameter creating apparatus 1 adjusts the exposure parameters used in the standard conditions (provisional exposure parameters explained later) to thereby determine exposure parameters in the new conditions.

The exposure-parameter creating apparatus 1 includes an input unit 11, a provisional-exposure-parameter setting unit 12, an evaluation-parameter creating unit 13, a PPE-fluctuation-information storing unit 14, a lithography-target setting unit 15, an exposure-parameter adjusting unit 16, an exposure-margin determining unit 17, an output unit 18, and a control unit 19.

The input unit 11 receives the input of design rules, exposing apparatus specifications, evaluation patterns, design specifications, PPE fluctuation information (process proximity effect fluctuation), and the like. The design rules are design rules for design data used in a semiconductor process. The exposing apparatus specifications are apparatus specifications of an exposing apparatus used for device manufacturing. Specifically, the exposing apparatus specifications are exposure wavelength, an adjustment range of a lens numerical aperture, a variability degree of an illumination shape, an adjustment range of lens aberration, fluctuation information of an exposure dose and focus, and the like.

Exposure patterns are patterns for checking exposure conditions and the like (patterns for dimension evaluation) and include various patterns such as a sparse pattern and a dense pattern. The sparse pattern is a pattern having a wide space between the pattern and an adjacent pattern. The dense pattern is a pattern having a narrow space between the pattern and an adjacent pattern. The evaluation patterns include various patterns determined from the design rules.

The device specifications are specifications of a device to be manufactured. The device specifications are determined from conditions for securing yield equal to or higher than a predetermined value when the device to be manufactured is mass-produced. The PPE fluctuation information is information concerning a pattern dimension due to process proximity effect of etching and the like. The PPE fluctuation information is different depending on a body of an etching apparatus or a design layout. The PPE fluctuation information includes information concerning fluctuation in proximity effect that occurs in processes other than the lithography process such as the etching process. The PPE fluctuation information in this embodiment includes a systematic component 21 and a random component 22.

The design rules and the exposing apparatus specifications input to the input unit 11 are sent to the provisional-exposure-parameter setting unit 12. The evaluation patterns input to the input unit 11 are sent to the evaluation-pattern creating unit 13. The PPE fluctuation information input to the input unit 11 is sent to the lithography-target setting unit 15 and the exposure-margin determining unit 17. The design specifications input to the input unit 11 are sent to the exposure-margin determining unit 17.

The provisional-exposure-parameter setting unit 12 provisionally sets, based on the exposing apparatus specifications and the design rules, exposure parameters (exposure parameters in the standard conditions) for forming evaluation patterns on a wafer. The provisionally-set exposure parameters may be referred to as provisional exposure parameters below. The provisional exposure parameters are, for example, a numerical aperture (NA) of a lens, an illumination light source shape, an inner diameter (σᵢₙ) of an illumination light source, an outer diameter (σₒᵤₜ) of the illumination light source, an angle (an angle of aperture of the illumination light source), an exposure dose (energy per unit area), and focus. The illumination light source shape is any one of, for example, zonal illumination, four-eye illumination (quadrupole illumination), and dipole illumination (double-pole illumination). The provisional-exposure-parameter setting unit 12 inputs the set provisional exposure parameters to the evaluation-parameter creating unit 13.

The evaluation-parameter creating unit 13 applies the OPC to the evaluation patterns using the set provisional exposure parameters to thereby create evaluation patterns after the OPC. The evaluation-pattern creating unit 13 inputs the created evaluation patterns after the OPC to the lithography-target setting unit 15. The PPE-fluctuation-information storing unit 14 is a memory or the like that stores the PPE fluctuation information input to the input unit 11.

The lithography-target setting unit 15 creates a lithography target (a target pattern (a target dimension) after exposure corresponding to the evaluation patterns after the OPC) using the systematic component 21 of the PPE fluctuation information stored by the PPE-fluctuation-information storing unit 14 to thereby set a plurality of lithography targets with fluctuation in a pattern dependent component of the PPE taken into account. Specifically, the lithography-target setting unit 15 sets mask data, with which a desired dimension is obtained as a post-processing dimension, taking the systematic component 21 into account and sets a lithography target corresponding to the mask data. The lithography-target setting unit 15 sends the set lithography target to the exposure-parameter adjusting unit 16.

The exposure-parameter adjusting unit 16 adjusts provisionally-set exposure parameters set such that a dimensional difference between a dimension of the lithography target set by the lithography-target setting unit 15 and a pattern dimension after exposure is small (e.g., within tolerance). The exposure-parameter setting unit 16 adjusts the exposure parameters to thereby set exposure parameters in the new conditions. The exposure-parameter adjusting unit 16 inputs the adjusted exposure parameters to the exposure-margin determining unit 17.

The exposure-margin determining unit 17 calculates an exposure margin in an exposure process using the exposure parameters adjusted by the exposure-parameter adjusting unit 16 and the random component 22 of the PPE fluctuation information stored by the PPE-fluctuation-information storing unit 14. The exposure-margin determining unit 17 determines, based on the design specifications input to the input unit 11, whether the calculated exposure margin is within tolerance. When the calculated exposure margin is within the tolerance, the exposure-margin determining unit 17 outputs the calculated exposure parameters from the output unit 18. When the calculated exposure margin is not within the tolerance, the exposure-margin determining unit 17 causes the exposure-parameter adjusting unit 16 to readjust the exposure parameters.

The control unit 19 controls the input unit 11, the provisional-exposure-parameter setting unit 12, the evaluation-parameter creating unit 13, the PPE-fluctuation-information storing unit 14, the lithography-target setting unit 15, the exposure-parameter adjusting unit 16, the exposure-margin determining unit 17, and the output unit 18.

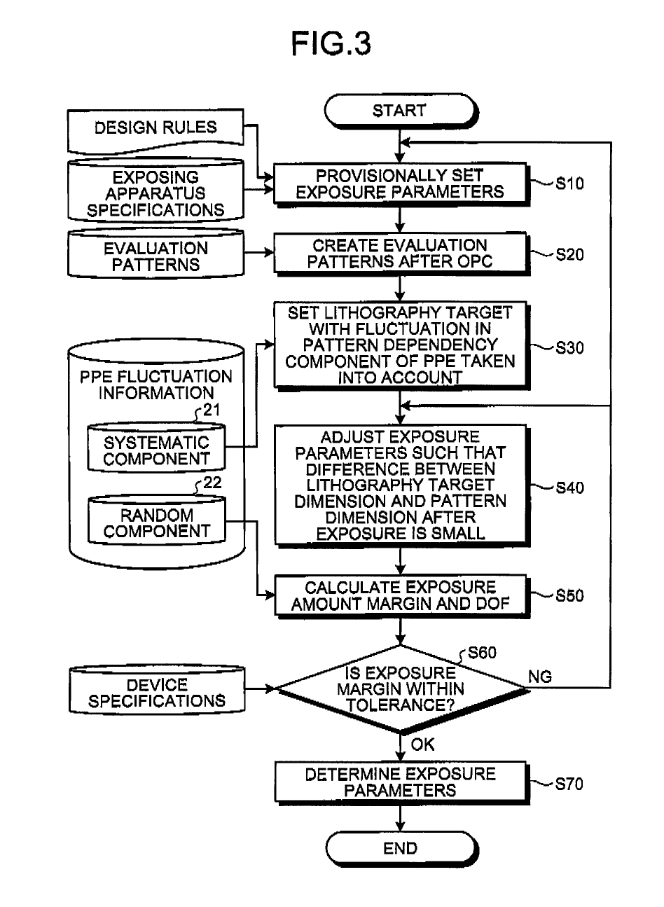

FIG. 3 is a flowchart for explaining a processing procedure of an exposure-parameter creating method according to this embodiment. The design rules, the exposing apparatus specifications, the evaluation patterns, the device specifications, the PPE fluctuation information, and the like are input to the input unit 11 of the exposure-parameter creating apparatus 1 in advance.

The design rules and the exposing apparatus specifications input to the input unit 11 are sent to the provisional-exposure-parameter setting unit 12. The evaluation patterns input to the input unit 11 are sent to the evaluation-pattern creating unit 13. The systematic component 21 of the PPE fluctuation information input to the input unit 11 is sent to the lithography-target setting unit 15. The random component 22 is sent to the exposure-margin determining unit 17. The device specifications input to the input unit 11 are sent to the exposure-margin determining unit 17.

The provisional-exposure-parameter setting unit 12 provisionally sets, based on the exposing apparatus specifications and the design rules, exposure parameters used in the exposure process (step S10). The provisional-exposure-parameter setting unit 12 inputs the set provisional exposure parameters to the evaluation-pattern creating unit 13.

The evaluation-pattern creating unit 13 applies the OPC to the evaluation patterns using the provisional exposure parameters to thereby create evaluation patterns after the OPC (step S20). Specifically, the evaluation-pattern creating unit 13 creates new evaluation patterns obtained by applying OPC correction for suppressing dimensional fluctuation due to layout dependency of a dimension to the evaluation patterns. The evaluation-pattern creating unit 13 inputs the created evaluation patterns after the OPC to the lithography-target setting unit 15.

The lithography-target setting unit 15 creates a lithography target using the systematic component 21 of the PPE fluctuation information stored by the PPE-fluctuation-information storing unit 14 to thereby set the lithography target with fluctuation in the pattern dependency component of the PPE taken into account (step S30). In other words, the lithography-target setting unit 15 corrects fluctuation in a process proximity effect, which occurs in processing processes other than exposure processing, to thereby create a lithography target and sets the lithography target. Specifically, the lithography-target setting unit 15 creates, based on a fluctuation amount of the systematic component 21, a plurality of target dimensions in the lithography process for the evaluation patterns. The lithography-target setting unit 15 sends the set lithography target to the exposure-parameter adjusting unit 16.

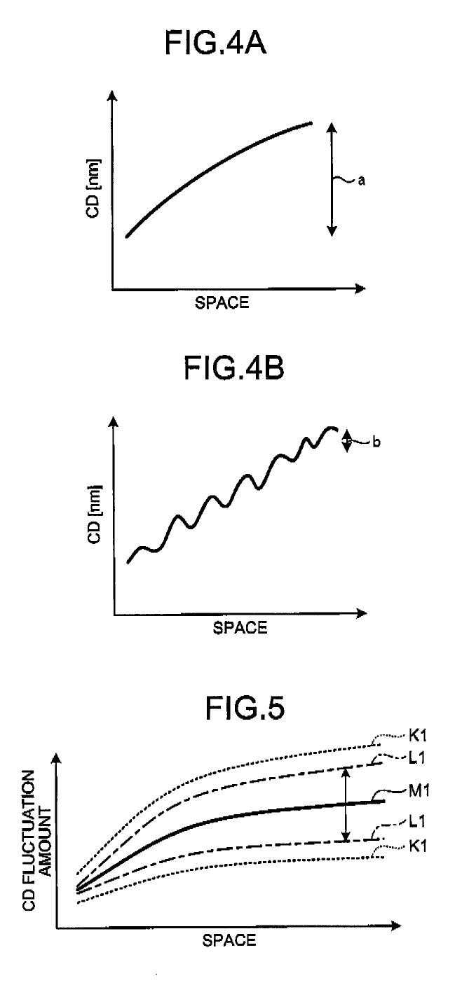

FIGS. 4A and 4B are graphs for explaining the systematic component 21 and the random component 22 of the PPE fluctuation information. In FIGS. 4A and 48, the abscissa indicates a space dimension (in the figure, described as Space) on design data and the ordinate indicates a finish pattern dimension (in the figure, described as CD). The space dimension is a distance between adjacent patterns. A pattern having a large space is a sparse pattern (a pattern having small pattern coverage). On the other hand, a pattern having a small space dimension is a dense pattern (a pattern having large pattern coverage). The pattern dimension is a dimension of a pattern after etching.

As shown in FIG. 4A, the pattern dimension fluctuates according to a change in the space dimension. Specifically, when a space dimension between a pattern to be transferred and a pattern adjacent to the pattern is changed with a pattern dimension of the pattern to be transferred fixed, as the space dimension increases, a pattern dimension after the etching increases. A fluctuation amount of the pattern dimension (a CD fluctuation amount “a”) is the systematic component 21 of the PPE fluctuation information. In other words, the systematic component 21 of the PPE fluctuation information is, for example, information that specifies a range of an average value of dimensional fluctuation due to the proximity effect (a fluctuation range) (a dimensional fluctuation amount due to the proximity effect) and is a systematic component in the proximity effect. The dimensional fluctuation range due to the proximity effect can be calculated by using various statistical methods such as the method of least squares, the Lagrange interpolation method, and the spline interpolation method.

As shown in FIG. 4B, when a space dimension between a pattern to be transferred and a pattern adjacent to the pattern is changed with a pattern dimension of the pattern to be transferred fixed, as the space dimension is changed, the pattern dimension fluctuates at random according to fluctuation in the pattern dimension corresponding to the change in the space dimension. A fluctuation amount of the random fluctuation (random fluctuation “b”) is the random component 22 of the PPE fluctuation information. In other words, the random component 22 is a component that fluctuates at random irrespectively of the change in the space dimension and is a fluctuation component obtained by deducting the fluctuation shown in FIG. 4A from the fluctuation shown in FIG. 4B (a component indicated by a wavy line in FIG. 4B).

FIG. 5 is a graph for explaining fluctuation in the PPE. In FIG. 5, a relation between a space dimension and a dimension fluctuation amount is shown. The abscissa indicates a space dimension (in the figure, described as Space) on design data and the ordinate indicates a finish dimension fluctuation amount (in the figure, described as CD fluctuation amount). Because the pattern dependency of the PPE fluctuates depending on conditions such as apparatus deployment and derived products, a center value (a center characteristic) M1 of the PPE fluctuates according to an etching process. A fluctuation characteristic L1 of the PPE shown in FIG. 5 is a dimensional fluctuation due to the systematic component 21. A fluctuation characteristic K1 of the PPE is a dimensional fluctuation due to the systematic component 21 and the random component 22.

In this embodiment, the lithography-target setting unit 15 creates a lithography target in advance using the systematic component 21 of the PPE fluctuation information. The exposure-parameter adjusting unit 16 adjusts exposure parameters such that a dimensional difference between a dimension of the lithography target set by the lithography-target setting unit 15 and a pattern dimension after exposure is small (step S40). In other words, the exposure-parameter adjusting unit 16 performs adjustment of the exposure parameters such that a dimensional difference between a target dimension in the lithography process and a post-exposure dimension is, for example, minimum. The post-exposure dimension can be obtained by an experiment or can be calculated by simulation. The exposure-parameter adjusting unit 16 inputs the adjusted exposure parameters to the exposure-margin determining unit 17.

The exposure-margin determining unit 17 calculates an exposure margin in the exposure process using the exposure parameters adjusted by the exposure-parameter adjusting unit 16 and the random component 22 of the PPE fluctuation information stored by the PPE-fluctuation-information storing unit 14. Specifically, the exposure-margin determining unit 17 calculates an exposure margin and a depth of focus (DOF) margin (a defocus margin) based on the pattern dimension and the target dimension after the adjustment of the exposure parameters and the random component 22 (step S50). When the random component 22 is taken into account, it is necessary to narrow the tolerance of the pattern dimension (after the exposure parameter adjustment) by a value corresponding to the random component 22. Therefore, the exposure-margin determining unit 17 deducts dimensional fluctuation corresponding to the random component 22 from the tolerance of the pattern dimension to thereby narrow the tolerance of the pattern dimension. The exposure-margin determining unit 17 derives an exposure margin and a DOF margin with which patterns having a pattern dimension within the narrowed tolerance can be formed. After calculating the exposure margin and the DOF margin with which patterns within the tolerance of the pattern dimension can be formed, the exposure-margin determining unit 17 can derive an exposure margin and a DOF margin by deducting a value corresponding to the random component 22 from the exposure margin and the DOF margin.

The exposure-margin determining unit 17 determines, based on the device specifications input to the input unit 11, whether the calculated exposure margin is within the tolerance (whether the calculated exposure margin satisfies the device specifications) (step S60). When the calculated exposure margin is within the tolerance (“OK” at step S60), the exposure-margin determining unit 17 determines the exposure parameters adjusted by the exposure-parameter adjusting unit 16 as exposure parameters (step S70). The output unit 18 outputs the determined exposure parameters to the outside.

On the other hand, when the calculated exposure margin is outside the tolerance (“NG” at step S60), the exposure-margin determining unit 17 causes the exposure-parameter adjusting unit 16 to readjust the exposure parameters. Consequently, the exposure-parameter adjusting unit 16 readjusts the exposure parameters such that a dimensional difference between the dimension of the lithography target and the pattern dimension after the exposure is small (step S40). The exposure-margin determining unit 17 calculates an exposure margin using the exposure parameters readjusted by the exposure-parameter adjusting unit 16 and the random component 22 of the PPE fluctuation information stored by the PPE-fluctuation-information storing unit 14 (step S50). The exposure-margin determining unit 17 determines, based on the design specifications, whether the calculated exposure margin is within the tolerance (step S60). When the calculated exposure margin is within the tolerance (“OK” at step S60), the exposure-margin determining unit 17 determines the exposure parameters readjusted by the exposure-parameter adjusting unit 16 as exposure parameters (step S70).

The exposure-parameter creating apparatus 1 repeats the processing at steps S40 to S60 until the calculated exposure margin falls within the tolerance. When exposure parameters are determined, the exposure-parameter creating apparatus 1 outputs the determined exposure parameters to the outside from the output unit 18. The output unit 18 can cause display means such as a liquid crystal monitor to display the determined exposure parameters or can send the exposure parameters to other apparatuses.

Exposure parameters are determined, for example, for each kind of exposure processing of a wafer process (e.g., for each layer or each mask). When exposure parameters in respective kinds of exposure processing are determined, exposure processing, etching, and the like of the wafer are performed by using the exposure parameters. Consequently, exposure processing according to the exposure parameters determined by the exposure-parameter creating apparatus 1 is performed in respective layers and a semiconductor device is manufactured.

The input of the evaluation patterns to the input unit 11 can be performed at any timing as long as the timing is before the creation of the evaluation patterns after the OPC by the evaluation-pattern creating unit 13. The input of the PPE fluctuation information to the input unit 11 can be performed at any timing as long as the timing is before the setting of the lithography target by the lithography-target setting unit 15. The input of the device specifications to the input unit 11 can be performed at any timing as long as the timing is before the calculation of the exposure margin by the exposure-margin determining unit 17.

In the explanation with reference to FIG. 3, when the calculated exposure margin is outside the tolerance (“NG” at step s60), the exposure-parameter adjusting unit 16 readjusts the exposure parameters (step S40). However, the provisional-exposure-parameter setting unit 12 can provisionally reset the exposure parameters. In this case, the processing at step S20 and subsequent steps is performed by using the provisionally-reset exposure parameters.

A part of the processing performed by the exposure-parameter creating apparatus 1 can be performed by another apparatus. For example, the processing for setting provisional exposure parameters, the processing for creating evaluation patterns after the OPC, and the processing for determining whether an exposure margin is within the tolerance can be performed by another apparatus. In this case, the provisional exposure parameters set by the other apparatus, the evaluation patterns after the CPC created by the other apparatus, a result of the determination whether the exposure margin is within the tolerance performed by the other apparatus, and the like are input to the exposure-parameter creating apparatus 1.

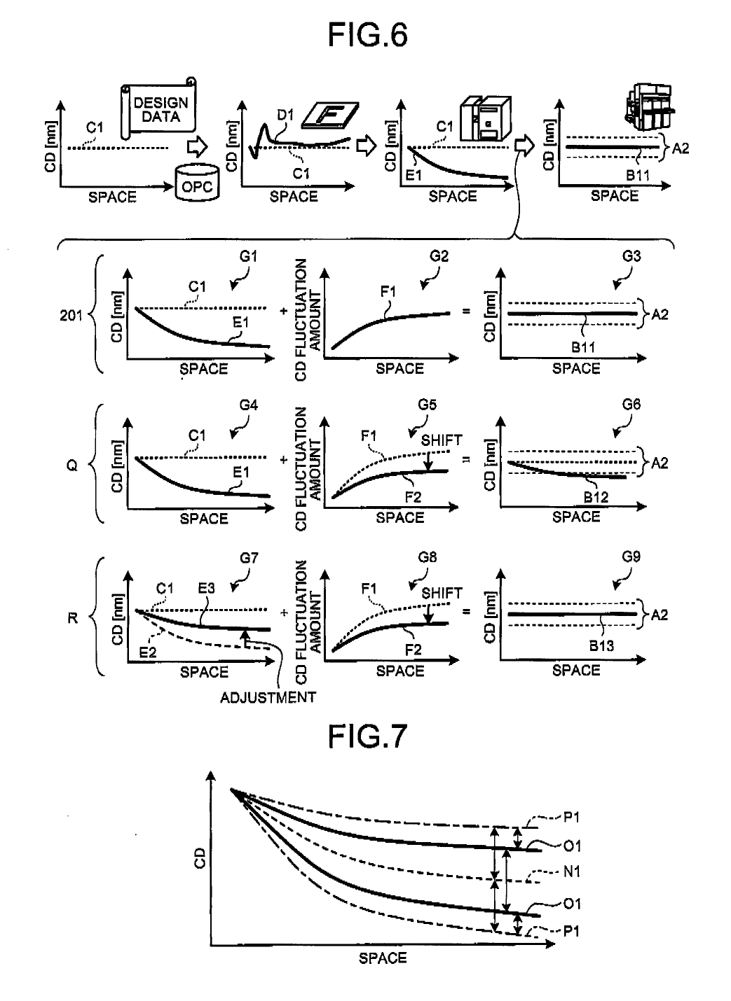

The pattern dimension (the design CD distribution) on the design data such as the design data 51 and 52, the pattern dimension (the reticle CD distribution) on the mask such as the reticles 61A and 61B, the resist pattern dimension after exposure (the post-lithography CD distribution), and the pattern dimension after etching (the post-processing CD distribution) are different from one another with respect to the space dimension. FIG. 6 is a diagram for explaining CD distributions in the respective processes. In FIG. 6, the abscissa indicates a space dimension (in the figure, described as Space) on design data and the ordinate indicates finish dimension (in the figure, described as CD).

In a top section of FIG. 6, a design CD distribution under the standard conditions, a reticle CD distribution under the standard conditions, a post-lithography CD distribution under the standard conditions, a post-processing CD distribution under the standard conditions are shown in order from the left to the right. In FIG. 6, the design CD distribution under the standard conditions is indicated by a design CD distribution C1, the reticle CD distribution under the standard conditions is indicated by a reticle CD distribution D1, the post-lithography CD distribution under the standard conditions is indicated by a post-lithography CD distribution E1, and the post-processing CD distribution under the standard conditions is indicated by a post-processing CD distribution B11. The reticle CD distribution D1 and the post-lithography CD distribution E1 are shift amounts with respect to the design CD distribution C1.

The design CD distribution C1 is fixed irrespectively of a space dimension. The reticle CD distribution D1 after the OPC is applied to the design data 51 and 52 having a design CD distribution is different from the design CD distribution C1. For example, the reticle CD distribution D1 substantially shifts from the design CD distribution C1 when the space dimension is small.

When processing such as etching is performed, a distribution of a pattern dimension with respect to the space dimension shifts. Therefore, the post-processing CD distribution B11 is obtained by adding up the post-lithography CD distribution E1 and a dimensional fluctuation distribution due to the PPE (PPE CD distribution) in processing. As shown in a second section from the top (graphs G1 to G3) in FIG. 6, under standard conditions 201, the post-lithography CD distribution E1 (a graph G1) and the dimensional fluctuation distribution F1 (a graph G2) due to the PPE are added up. Consequently, the post-processing CD distribution B11 (a graph G3) is in substantially the center in the tolerance A2.

In a third section from the top (graphs G4 to G6) in FIG. 6, for example, the standard conditions 201 are changed to conditions Q as conditions such as apparatus deployment and derived products by, for example, changing the body of the etching apparatus. In this case, according to the change from the standard conditions 201 to the conditions Q, the PPE in processing changes. In the graph G5 shown in FIG. 6, the dimensional fluctuation distribution F1 in the standard conditions 201 changes to a dimensional fluctuation distribution F2 under the conditions Q. Therefore, under the conditions Q, when the post-lithography CD distribution E1 (the graph G4) and the dimensional fluctuation distribution F2 (the graph G5) due to the PPE in processing are added up, the post-processing CD distribution B12 (the graph G6) may deviate from the tolerance A2.

In a fourth section from the top (graphs G7 to G9) in FIG. 6, for example, the standard conditions 201 are changed to conditions R by, for example, changing the body of the etching apparatus. The conditions R are obtained by adjusting the exposure parameters while changing the standard conditions 201 to the conditions Q as conditions such as apparatus deployment and derived products. In this case, according to the change from the standard conditions 201 to the conditions R, the PPE in processing changes in the same manner as in the conditions Q. In the graph G8, the dimensional fluctuation distribution F1 in the standard conditions 201 changes to the dimensional fluctuation distribution F2 under the conditions R. Because the exposure parameters are adjusted, a post-lithography CD distribution E2 is adjusted to a post-lithography CD distribution E3 under the conditions R. The adjustment of the exposure parameters is performed such that a post-processing CD distribution B13 (the graph G9) is substantially in the center in the tolerance A2 when the post-lithography CD distribution E3 (the graph G7) and the dimensional fluctuation distribution F2 (the graph G8) due to the PPE are added up. Consequently, when exposure or etching is performed under the conditions R, the post-processing CD distribution B13 having a distribution of pattern dimensions same as the post-processing CD distribution B11 under the standard conditions can be obtained.

FIG. 7 is a graph for explaining a dimension of a lithography target. In FIG. 7, a relation between a space dimension and a pattern dimension is shown. In FIG. 7, the abscissa indicates the space dimension (in the figure, described as Space) and the ordinate indicates the pattern dimension (in the figure, described as CD). A dimensional characteristic N1 is a post-lithography dimension obtained when the lithography target is exposed with provisional exposure parameters. A dimensional characteristic P1 is a dimensional characteristic of the lithography target with a dimensional fluctuation amount due to the systematic component 21 taken into account. Because the pattern dependency of the PPE fluctuates according to fluctuation in conditions such as apparatus deployment and derived products in this way, the lithography has a difference in dimensional fluctuation by an amount due to the systematic component 21. Therefore, in this embodiment, the exposure-parameter adjusting unit 16 adjusts the exposure parameters such that a dimensional difference between the dimension of the lithography target and the pattern dimension after exposure is small. Consequently, the dimensional characteristic P is a dimensional characteristic O1 of the lithography target having a small dimensional fluctuation amount.

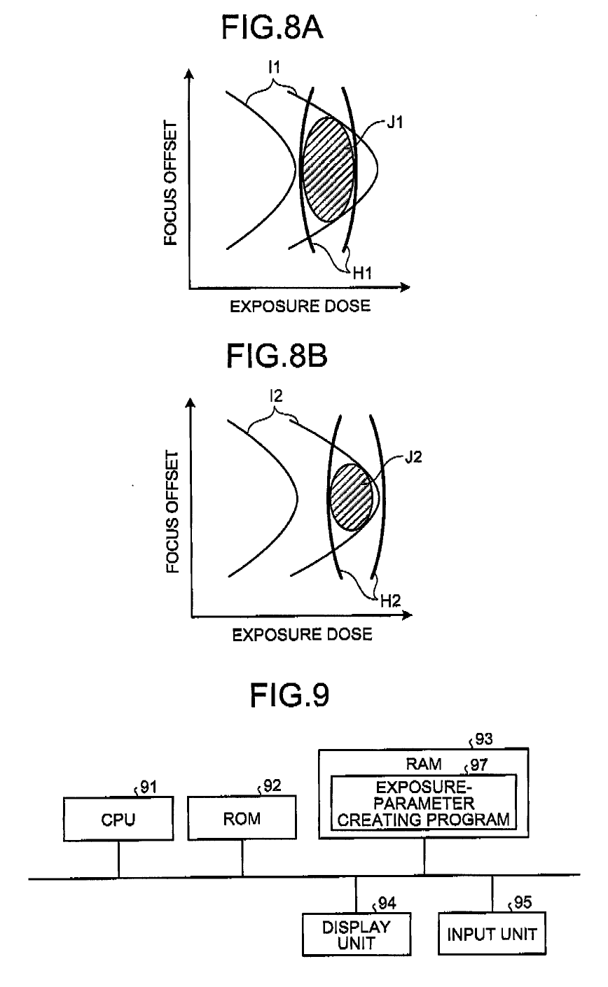

FIGS. 8A and 8B are graphs for explaining an exposure margin set when exposure conditions are not adjusted. In FIGS. 8A and 8B, the abscissa indicates an exposure dose and the ordinate indicates focus offset. FIG. 8A is a graph for explaining an exposure margin in the case of standard conditions (the standard conditions 201 shown in FIG. 6). FIG. 8B is a graph for explaining an exposure margin set when the exposure conditions are not adjusted (the conditions Q shown in FIG. 6).

Characteristics H1 and H2 and characteristics I1 and I2 indicate relations between an exposure dose and focus offset. Each of the characteristics H1 and H2 and the characteristics I1 and I2 is indicated by two lines. An area between the two lines indicates tolerances of the exposure dose and the focus offset with which patterns having a tolerance dimension can be formed. The characteristics H1 and H2 are characteristics in the case of a dense pattern and the characteristics I1 and I2 are characteristics in the case of a sparse pattern. When pattern density is changed from dense to sparse, the characteristic H1 changes to the characteristic I1 and the characteristic H2 changes to the characteristic I2.

Under the conditions 201 shown in FIG. 8, an area satisfying the characteristics H1 and I1 at a probability equal to or higher than a predetermined value in an area surrounded by both the characteristic H1 and the characteristic I1 is a focus margin area J1 indicated by an elliptical shape. Similarly, when the exposure conditions shown in FIG. 8B are not adjusted, an area satisfying the characteristics H2 and I2 at a probability equal to or higher than the predetermined value in an area surrounded by both the characteristic H2 and the characteristic I2 is a focus margin area J2 indicated by an elliptical shape. Under the standard conditions 201, whereas the exposure margin area J1 is large, when the PPE changes according to processing, the exposure margin area J2 decreases unless the exposure conditions are adjusted.

FIG. 9 is a diagram of the hardware configuration of an exposure-parameter creating apparatus. An exposure-parameter creating apparatus 1 includes a central processing unit (CPU) 91, a read only memory (ROM) 92, a random access memory (RAM) 93, a display unit 94, and an input unit 95. In the exposure-parameter creating apparatus 1, the CPU 91, the ROM 92, the RAM 93, the display unit 94, and the input unit 95 are connected to one another via a bus line.

The CPU 91 performs creation of exposure parameters using an exposure-parameter creating program 97 as a computer program for performing setting and adjustment of exposure parameters. A display unit 94 is a display device such as a liquid crystal monitor. The display unit 94 displays, based on an instruction from the CPU 91, design rules, exposing apparatus specifications, evaluation patterns, PPE fluctuation information, device specifications, provisional exposure parameters, evaluation parameters after OPC, an exposure margin, exposure parameters, and the like. The input unit 95 includes a mouse and a keyboard and receives the input of instruction information (e.g., information necessary for creation of exposure parameters) input by a user from the outside. The instruction information input to the input unit 95 is sent to the CPU 91.

The exposure-parameter creating program 97 is stored in the ROM 92 and loaded to the RAM 93 via the bus line. The CPU 91 executes the exposure-parameter creating program 97 loaded in the RAM 93. Specifically, in the exposure-parameter creating apparatus 1, the CPU 91 reads out, according to instruction input by the user from the input unit 95, the exposure-parameter creating program 97 from the ROM 92, expands the exposure-parameter creating program 97 in a program storage area in the RAM 93, and executes various kinds of processing. The CPU 91 temporarily stores various data generated in the various kinds of processing in a data storage area formed in the RAM 93.

In the explanation of the embodiment, the exposure-parameter creating apparatus 1 includes the PPE-fluctuation-information storing unit 14. However, the exposure-parameter creating apparatus 1 does not have to include the PPE-fluctuation-information storing unit 14. When the exposure-parameter creating apparatus 1 does not include the PPE-fluctuation-information storing unit 14, PPE fluctuation information input from the input unit 11 is stored in the lithography-target setting unit 15 or the exposure-margin determining unit 17.

In the explanation of the embodiment, the processing process other than the exposure process is etching. However, the processing process other than the exposure process can be a film formation process, a chemical mechanical polishing (CMP) process, or the like. Further, the processing process other than the exposure process can be a process as a combination of the etching, the film formation process, the CMP, and the like. When the processing process other than the exposure process is the film formation process or the CMP process, the PPE fluctuation information is a dimensional fluctuation amount of proximity effect that occurs in the film formation process or the CMP process.

As explained above, according to the embodiment, a lithography target is set, exposure parameters are adjusted by using the systematic component 21 of the PPE fluctuation information, and an exposure margin is calculated by using the random component 22 of the PPE fluctuation information. Therefore, it is possible to easily create appropriate exposure parameters. During readjustment of the exposure parameters, because it is unnecessary to perform the OPC, it is possible to easily adjust the exposure parameters. Because the lithography target is set based on the PPE fluctuation information and, thereafter, the exposure parameters are adjusted, it is possible to easily adjust the exposure parameters in a short time. Therefore, it is possible to easily reduce dimensional fluctuation in patterns formed on a semiconductor substrate.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor-device manufacturing method comprising:
correcting fluctuation in process proximity effect, which occurs in a process including a processing process other than exposure processing in forming a pattern on a semiconductor substrate, to thereby set a target pattern after exposure formed on a resist for forming the pattern;
adjusting an exposure parameter used in the exposure processing on the semiconductor substrate such that a difference between a dimension of the target pattern and a pattern dimension after the exposure is within tolerance;
calculating an exposure margin of the pattern using the exposure parameter and determining whether the exposure margin is within tolerance;
determining, when it is determined that the exposure margin is within the tolerance, the adjusted exposure parameter as an exposure parameter used in the exposure processing on the semiconductor substrate;
performing the exposure processing on the semiconductor substrate using the determined exposure parameter to thereby form a pattern on the semiconductor substrate;
setting, in setting the target pattern, the target pattern using a systematic component in the process proximity effect; and
calculating, in calculating the exposure margin, the exposure margin using a random component, which fluctuates at random, in fluctuation of the process proximity effect.

2. The semiconductor-device manufacturing method according to claim 1, further comprising:
readjusting the exposure parameter when it is determined that the exposure margin is not within the tolerance;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

3. The semiconductor-device manufacturing method according to claim 1, further comprising provisionally setting, before setting the target parameter, the exposure parameter as a provisionally-set exposure parameter based on a specification of an exposing apparatus used in the exposure processing and a design rule used in forming the pattern, wherein
the target pattern is set by using the provisionally-set exposure parameter, and
the exposure parameter is adjusted by using the provisionally-set exposure parameter.

4. The semiconductor-device manufacturing method according to claim 3, further comprising:
readjusting the provisionally-set exposure parameter when it is determined that the exposure margin is not within the tolerance;
thereafter setting the target pattern using the readjusted provisionally-set exposure parameter;
readjusting the exposure parameter using the readjusted provisionally-set exposure parameter;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

5. The semiconductor-device manufacturing method according to claim 1, wherein
the systematic component is a fluctuation amount due to proximity effect of a finish pattern dimension that changes according to a dimension of a space between patterns, and
the semiconductor-device manufacturing method further comprises setting, in setting the target pattern, mask data based on the systematic component such that a pattern formed on the semiconductor substrate has a desired dimension and setting a target pattern corresponding to the mask data.

6. The semiconductor-device manufacturing method according to claim 1, wherein
the random component is a fluctuation amount due to proximity effect of a finish pattern dimension that fluctuates irrespectively of a dimension of a space between patterns, and
the semiconductor-device manufacturing method further comprises performing calculation of the exposure margin such that a pattern dimension of the pattern is within the tolerance narrowed by deducting, in performing calculation of the exposure margin, dimensional fluctuation corresponding to the random component from tolerance of the pattern dimension.

7. The semiconductor-device manufacturing method according to claim 1, wherein the exposure parameter is at least one of exposure wavelength, a numerical aperture of a lens, an illumination light source shape, an inner diameter of an illumination light source, an outer diameter of the illumination light source, an angle of aperture of the illumination light source, a luminance distribution of illumination, an exposure dose, and focus.

8. A computer program product having a computer-readable recording medium including a plurality of commands for determining an exposure parameter executable in a computer, the commands causing the computer to execute:
correcting fluctuation in process proximity effect, which occurs in a process including a processing process other than exposure processing in forming a pattern on a semiconductor substrate, to thereby set a target pattern after exposure formed on a resist for forming the pattern;
adjusting an exposure parameter used in the exposure processing on the semiconductor substrate such that a difference between a dimension of the target pattern and a pattern dimension after the exposure is within tolerance;
calculating an exposure margin of the pattern using the exposure parameter and determining whether the exposure margin is within tolerance;
determining, when it is determined that the exposure margin is within the tolerance, the adjusted exposure parameter as an exposure parameter used in the exposure processing on the semiconductor substrate;
setting, in setting the target pattern, the target pattern using a systematic component in the process proximity effect; and
calculating, in calculating the exposure margin, the exposure margin using a random component, which fluctuates at random, in fluctuation of the process proximity effect.

9. The computer program product according to claim 8, further causing the computer to execute:
readjusting the exposure parameter when it is determined that the exposure margin is not within the tolerance;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

10. The computer program product according to claim 8, further causing the computer to execute provisionally setting, before setting the target parameter, the exposure parameter as a provisionally-set exposure parameter based on a specification of an exposing apparatus used in the exposure processing and a design rule used in forming the pattern, wherein
the target pattern is set by using the provisionally-set exposure parameter, and
the exposure parameter is adjusted by using the provisionally-set exposure parameter.

11. The computer program product according to claim 10, further causing the computer to execute:
readjusting the provisionally-set exposure parameter when it is determined that the exposure margin is not within the tolerance;
thereafter setting the target pattern using the readjusted provisionally-set exposure parameter;
readjusting the exposure parameter using the readjusted provisionally-set exposure parameter;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

12. The computer program product according to claim 8, wherein
the systematic component is a fluctuation amount due to proximity effect of a finish pattern dimension that changes according to a dimension of a space between patterns, and
the computer program product further causes the computer to execute setting, in setting the target pattern, mask data based on the systematic component such that a pattern formed on the semiconductor substrate has a desired dimension and setting a target pattern corresponding to the mask data.

13. The computer program product according to claim 8, wherein
the random component is a fluctuation amount due to proximity effect of a finish pattern dimension that fluctuates irrespectively of a dimension of a space between patterns, and
the computer program product further causes the computer to execute performing calculation of the exposure margin such that a pattern dimension of the pattern is within the tolerance narrowed by deducting, in performing calculation of the exposure margin, dimensional fluctuation corresponding to the random component from tolerance of the pattern dimension.

14. The computer program product according to claim B, wherein the exposure parameter is at least one of exposure wavelength, a numerical aperture of a lens, an illumination light source shape, an inner diameter of an illumination light source, an outer diameter of the illumination light source, an angle of aperture of the illumination light source, a luminance distribution of illumination, an exposure dose, and focus.

15. An exposure-parameter creating method, comprising:
correcting fluctuation in process proximity effect, which occurs in a process including a processing process other than exposure processing in forming a pattern on a semiconductor substrate, to thereby set a target pattern after exposure formed on a resist for forming the pattern;
adjusting an exposure parameter used in the exposure processing on the semiconductor substrate such that a difference between a dimension of the target pattern and a pattern dimension after the exposure is within tolerance;
calculating an exposure margin of the pattern using the exposure parameter and determining whether the exposure margin is within tolerance;
determining, when it is determined that the exposure margin is within the tolerance, the adjusted exposure parameter as an exposure parameter used in the exposure processing on the semiconductor substrate;
performing the exposure processing on the semiconductor substrate using the determined exposure parameter to thereby form a pattern on the semiconductor substrate;
setting, in setting the target pattern, the target pattern using a systematic component in the process proximity effect; and
calculating, in calculating the exposure margin, the exposure margin using a random component, which fluctuates at random, in fluctuation of the process proximity effect.

16. The exposure-parameter creating method according to claim 15, further comprising:
readjusting the exposure parameter when it is determined that the exposure margin is not within the tolerance;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

17. The exposure-parameter creating method according to claim 15, further comprising provisionally setting, before setting the target parameter, the exposure parameter as a provisionally-set exposure parameter based on a specification of an exposing apparatus used in the exposure processing and a design rule used in forming the pattern, wherein
the target pattern is set by using the provisionally-set exposure parameter, and
the exposure parameter is adjusted by using the provisionally-set exposure parameter.

18. The exposure-parameter creating method according to claim 17, further comprising:
readjusting the provisionally-set exposure parameter when it is determined that the exposure margin is not within the tolerance;
thereafter setting the target pattern using the readjusted provisionally-set exposure parameter;
readjusting the exposure parameter using the readjusted provisionally-set exposure parameter;
thereafter determining, when it is determined that the exposure margin is within the tolerance, the readjusted exposure parameter as an exposure parameter used in the exposure processing on the semiconductor substrate; and
performing the exposure processing on the semiconductor substrate using the determined exposure parameter to thereby form a pattern on the semiconductor substrate.

19. The exposure-parameter creating method according to claim 15, wherein
the systematic component is a fluctuation amount due to proximity effect of a finish pattern dimension that changes according to a dimension of a space between patterns, and
the exposure-parameter creating method further comprises setting, in setting the target pattern, mask data based on the systematic component such that a pattern formed on the semiconductor substrate has a desired dimension and setting a target pattern corresponding to the mask data.

20. The exposure-parameter creating method according to claim 15, wherein
the random component is a fluctuation amount due to proximity effect of a finish pattern dimension that fluctuates irrespectively of a dimension of a space between patterns, and
the exposure-parameter creating method further comprises performing calculation of the exposure margin such that a pattern dimension of the pattern is within the tolerance narrowed by deducting, in performing calculation of the exposure margin, dimensional fluctuation corresponding to the random component from tolerance of the pattern dimension.
